(19) United States
(12) Patent Application Publication
(10) Pub. No.: US 2022/0299703 A1
(43) Pub. Date: Sep. 22, 2022

(54) Electro-optical device via arrangement

(71) Applicant: Teknologian tutkimuskeskus VTT Oy, Espoo (FI)

(72) Inventor: Giovanni Delrosso, Espoo (FI)

(21) Appl. No.: 17/693,476

(22) Filed: Mar. 14, 2022

(30) Foreign Application Priority Data
Mar. 16, 2021 (FI) 20215286

(51) Int. Cl. G02B 6/02; G02B 6/12; G01R 31/26

(52) U.S. Cl. CPC G02B 6/02; G02B 6/12; G01R 31/2635

(57) ABSTRACT

According to an example aspect of the present invention, there is provided an electro-optical device, comprising: a planar first substrate, a first electric contact point on a first side of the first substrate, a second electric contact point on a second side of the first substrate, and a via arrangement configured to provide electric contact between the first electric contact point and the second electric contact point. The via arrangement comprises a fiber optic portion and an electrically conductive portion, wherein the electrically conductive portion is arranged between the fiber optic portion and the first substrate and is configured to electrically connect the first electric contact point and the second electric contact point.

### FIELD

The present invention relates to via arrangements for substrates of electronic devices, and particularly electro-optical devices.

### BACKGROUND

A via may generally refer to a though-hole in an intermediate substrate. Through silicon vias (TSV) are widely used and refer to interconnecting holes between top and bottom sides of a silicon wafer substrate. The substrate may comprise glass and comprise through glass vias (TGV). Electrical connection may be arranged between opposite sides of an electrically-insulated substrate by positioning electrically conducting material in the via, such as conductive pillar e.g. of copper.

Electro-optical devices may include various semiconductor devices with both optical and electrical portions. Silicon photonics chips comprising optical integrated circuits (OICs) and electrical integrated circuits (EICs) are exemplary of such semiconductor devices. In electro-optical devices vias are often required for both electrical and optical connection.

Micro-optoelectromechanical systems (MOEMS), also known as optical MEMS, may be considered as systems involving sensing or manipulating optical signals on a very small size scale, using integrated mechanical, optical, and electrical systems. Forming an electrical interconnection by, for example, a TSV for MOEMS device, may be a complex and expensive process. There is a need for improvements for via arrangements.

### SUMMARY OF THE INVENTION

The scope of the invention is defined in the independent claims. Some embodiments are defined in the dependent claims.

According to an aspect, there is provided an electro-optical device, comprising: a planar first substrate, a first electric contact point on a first side of the first substrate, a second electric contact point on a second side of the first substrate, and a via arrangement configured to provide electric contact between the first electric contact point and the second electric contact point. The via arrangement comprises a fiber optic portion and an electrically conductive portion, wherein the electrically conductive portion is arranged between the fiber optic portion and the first substrate and is configured to electrically connect the first electric contact point and the second electric contact point. The device further comprises a second substrate and a photonic device on the second substrate. The fiber optic portion may be adapted to extend towards the photonic device or connect the photonic device for illumination or light coupling to or from the photonic device. The electro-optical device comprises or is included in a quantum computing or cryogenic electro-optical module. The photonic device is a fiber optic meander, a single-flux quantum electronic circuit or a photodiode of the quantum computing or cryogenic electro-optical module.

According to an embodiment, the via arrangement is insertable or inserted into and removable from a through silicon or through glass via formed between the first side and the second side of the first substrate.

The first substrate may be an illumination carrier. A plurality of via arrangements and respective photonic devices may be arranged in such device. At least one of the electric contact points may be arranged for testing the photonic device by a test probe on the first substrate.

According to an embodiment, the electrically conducting portion is a conductive coating around cladding of the fiber optic portion. The conductive coating can, however, in some other embodiments be provided around a portion (of the fiber optic portion) other than cladding of the fiber optic portion, such as a core, inner primary coating or a secondary outer coating of the fiber optic portion.

According to an embodiment, the device further comprises a third substrate (22), a third electric contact point (46) on a first side of the third substrate, a fourth electric contact point (48) on a second side of the third substrate. The device may further comprise a further via arrangement portion, which may comprise a further electrically conductive portion (14a) provided around the fiber optic portion (12a) extending through the third substrate and configured to electrically connect the third electric contact point and the fourth electric contact point. In an embodiment, a single electrically conductive portion around the fiber optic portion extends through the first substrate (20) and the third substrate.

### BRIEF DESCRIPTION OF THE DRAWINGS

FIGS. 1A, 1B, and 2 illustrate sectional or side views of an electro-optical arrangement in accordance with at least some embodiments;

FIG. 3 illustrates an example of monolithically integrated electro-optical device in accordance with at least some embodiments;

FIG. 4 illustrates an example of a hybridly integrated electro-optical device in accordance with at least some embodiments;

FIG. 5 illustrates an example of a stacked electro-optical device in accordance with at least some embodiments;

FIG. 6 illustrates a side view example of an illuminator carrier in accordance with at least some embodiments; and

FIG. 7 illustrates a top view example of an illuminator carrier in accordance with at least some embodiments.

### EMBODIMENTS

A via arrangement is now provide for electro-optical devices, such as MOEMS devices, insertable to a via of a planar substrate, to provide electrical conductivity between opposite sides of the substrate, as well as delivery of optical signals through the substrate. Some embodiments for an apparatus or electro-optical device comprising such via arrangement are further illustrated below.

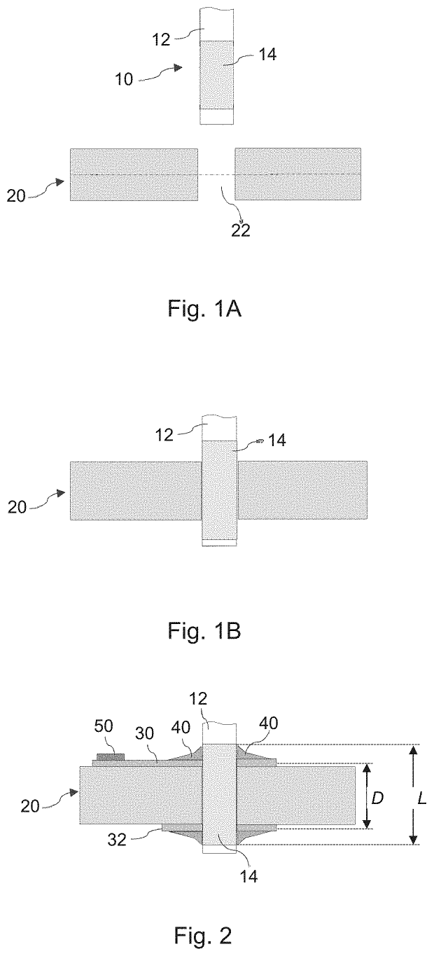

With reference to simplified examples of FIGS. 1A and 1B, a via 22 is formed in a planar substrate 20 for a microelectronic device. The substrate comprises insulating material, such as silicon, glass, or ceramic material.

A via arrangement 10 is configured to provide electric contact between opposite (first/top and second/bottom) sides of the substrate 20, and in particular respective (first and second) electric contact points on these opposite sides (not separately illustrated). The via arrangement 10 comprises a fiber optic portion (FOP) 12 capable of passing an optical signal. Light is guided in a core of the FOP by an optical cladding around the core. One or more protective coating layers may be applied around the optical cladding, such as an inner primary coating and a secondary outer coating protecting a primary coating in dual-coating solutions. Examples of applicable optic fibers include various already available glass fibers, such as Corning® SMF-28 fibers, e.g. SMF-28e, or similar fibers. However, it is to be appreciated that these are just examples and various other types of optical fibers may be applied.

The via arrangement 10 further comprises an electrically conductive portion (ECP) 14 coupled with at least a portion and at least one area or side of the FOP 12. An electrically conductive material, suitable to be at least partially adapted on the optical fibre may be used. The ECP 14 may comprise metal, such as molybdenum, aluminum or copper.

In some embodiments, the FOP is circular, and the ECP 14 is annular and surrounds the FOP 12. The ECP 14 may be a conductive coating or metallization attached around cladding or further protective coating of the FOP 12. The conductive coating can, however, in some other embodiments be provided around a portion (of the FOP 12) other than cladding, such as a core, inner primary coating or a secondary outer coating of the FOP 12. A variety of shapes is available to arrange termination of the optic fiber.

The ECP 14 of the via arrangement 10 may extend only at one lateral/longitudinal side of the substrate 20, or cover or extend to multiple lateral sides of the via 22, or entirely surround the FOP 12 and be available at all positions on both sides of the via 22, depending on the required electrical interconnection(s) and manufacturing technique. As further illustrated in FIG. 1B, the via arrangement 10 may be insertable into and removable from the via 22.

At least one electric contact point or pad is provided at both of the opposite sides of the substrate 20, adapted in electric contact with the ECP 14 when the via arrangement 10 is positioned in the device to extend to both sides. FIG. 2 further illustrates conductive pads 30, 32 added on both sides of the substrate 20. The pads 30, 32 are electrically connected by the ECP when the via arrangement is in position. The (transversal or cross-longitudinal) length L of the ECP 12 is equal to or greater than distance D between electric contact points, such as the pads in this example, on the opposite sides of the substrate 20. In some embodiments, one end of the via 22 is widened and wider than the other end of the via, to further facilitate insertion of the via arrangement.

It is to be appreciated that there may be multiple separate ECPs on the FOP 12, and coverage of the ECP 14 does not have to be limited to extend to merely connect the pads, but can cover extend further along the FOP on either or both sides of the substrate 20, depending on the applied implementation and electrical connectivity requirements. In some embodiments, the contact pad may be annular, around the via 22. The present example illustrates pads coaxially on both lateral sides of the via 22, but it is to be appreciated that a pad may be applied only at one side in relation to the ECP 14, separate pads may be applied at the same side of the substrate, and/or the ECP may be applied only at a sub-area of the via. This, however causes further requirements for positioning the via arrangement and the ECP 14, such that the ECP 14 is in a correct pose in relation to the respective electric contact point so as to ensure appropriate electric contact.

FIG. 2 also illustrates that solder layer(s), solder preform(s), or solder(s) 40 may be added on pads 30, 32 on at least one side of the substrate 20, to further ensure the mounting of the via arrangement 10 in the via 22. In an example embodiment, electrically conductive adhesive is applied. In a further embodiment, L is greater than distance between (outer edges of) the solders at different sides of the substrate 20. L may be a greater than this distance D, wherein a may be at least 5% greater, for example. This enables to further ensure electric conductivity despite small positioning error.

It will be appreciated that various further layers and components may be added. For example, an electronic device may be added on a layer on the substrate 20, and the electronic device may be electronic connected to the ECP 14 and thus further to an electric circuit on the other side of the substrate. In the present example, the pad (or electric contact point layer) 30 is extended from the via to form a connection line such that an electronic device or electric contact point 50 is connected on the pad 30.

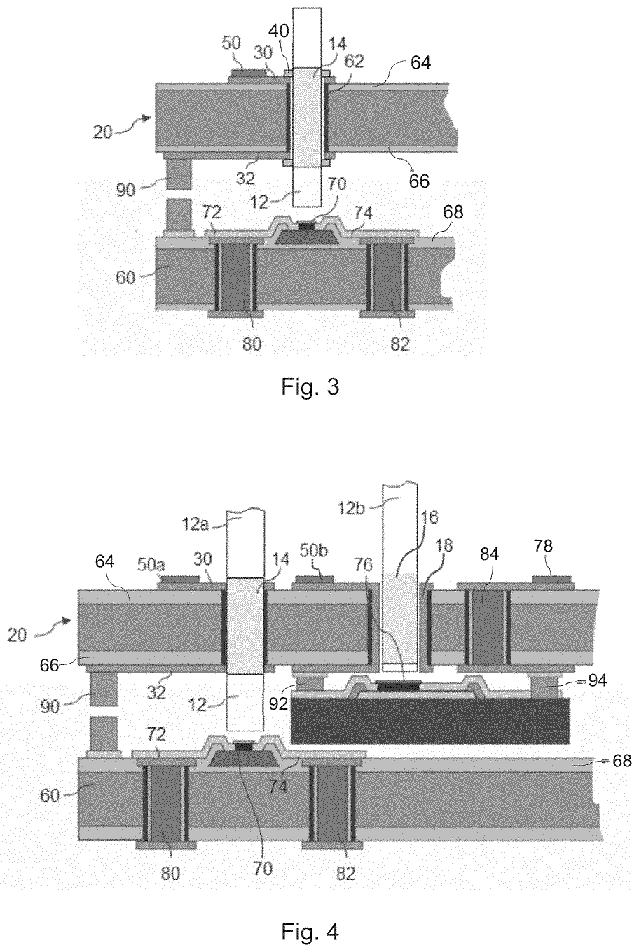

With reference to FIG. 3, in some embodiments the electro-optical device or apparatus comprises a second substrate 60 and a photonic device 70 on the second substrate. FIG. 3 illustrates an arrangement of monolithically integrated electro-optical device 70. The substrate 20, 60 may be a wafer or panel comprising silicon, glass or ceramic material. The FOP 12 is adapted to extend towards the photonic device 70. The FOP 12 may be adapted to connect the photonic device 70 for illumination or light coupling, to deliver and/or receive optical signal to/from the photonic device. The photonic device 70 may be connected to one or more electrically conducting lines 72, 74, which may be further connected to further electronic device(s) on the second substrate 60 and/or as in the present example, to electrically conductive portions of vias 80, 82 for providing a signal from or to a connector on the other side of the second substrate 60. For example, the via 80, 82 may be a filled TSV, comprising conductive material, such as copper, and further dielectric may surround the conductive material.

A pedestal, or a wall structure, which is hermetically closed chip volume, is also illustrated by reference 90. It is to be noted that in this example Figure the pedestal 90 is not connected to (a below pedestal) of the substrate 60, i.e. a gap is visible at this point between substrates 20 and 60, so the pedestal(s) or pillar(s) between the substrates are not (yet) connecting the substrates together. It will be appreciated that the pedestal 90 may be continuous and connect the substrates 20 and 60 together in the final construction.

A further dielectrive layer 62 may be arranged between the ECP 14 and the substrate 20. For example, silicon dioxide (SiO₂) or aluminium oxide (Al₂O₃) layer may be applied. Dielectrive layers 64, 66 are also illustrated on both sides of the substrate 20. Dielectric layer(s) 68 may also be arranged on the second substrate 60. Such dielectrive layers may be needed particularly for silicon-based wafers, but may be avoided in case of non-silicon wafers, such as plastic of quartz-based wafers.

The electro-optical device may comprise or be included in a cryogenic electro-optical module. The electro-optical device may comprise or be included in a quantum computing (cryogenic or non-cryogenic) electro-optical module. The (first) substrate 20 may be an illumination or illuminator carrier. The photonic device 70 may be a fiber optic meander, a photodiode, or a single-flux quantum (SFQ) electronic circuit of a quantum computing or cryogenic electro-optical module. In a still further example, the photonic device may be a laser chip or a photodiode in a standard high-capacity transceiver module, for example. However, it will be appreciated that these are just some examples, and the present via arrangement may be applied in connection with various other hermetic electro-optical interconnections, electro-optical modules and electro-optical communication applications and devices.

FIG. 4 illustrates an example of a hybridly integrated electro-optical device. A hybridly integrated electro-optical device 76 is connected by pedestals or pillars 92, 94 to the same substrate 20 as the associated FOP 12b. In the present example the pillars 92, 94 comprise conductive material and a further electrically conductive portion 18 is connecting an electronic device 50b to components on the other side of the substrate 20, such as the device 76. The FOP 12b may comprise an ECP 16, similarly as the other FOP 12a (although not necessary due to the portion 18 illustrated between the substrate 20 and the ECP 16 in this example). An advantage of the present via arrangement 10 is that difficult addition/coating procedure of such portions 18 in the via 22 of the substrate 20 may be avoided. This facilitates easier and less expensive fabrication. A further electric contact point 78 on top surface of the substrate 20 and connected to the device 76 through a conductive portion of a further via 84 and the pillar 94 is also illustrated.

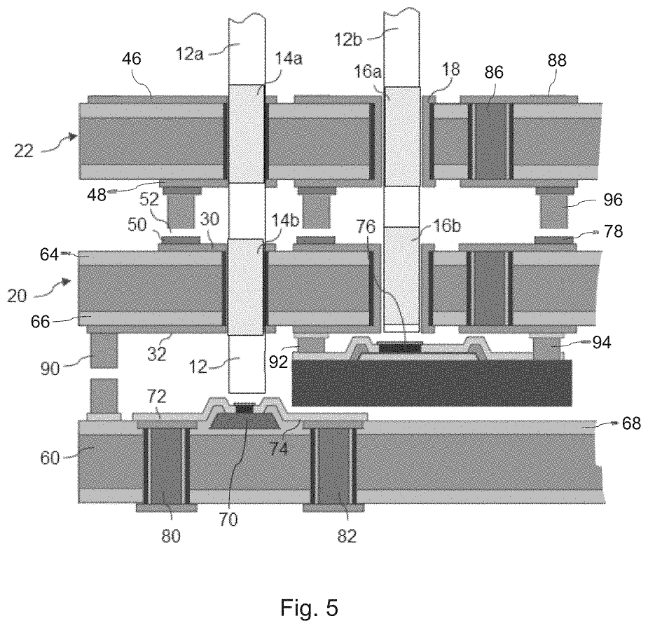

FIG. 5 illustrates an example of an electro-optical device with 3D wafer level package (WLP) stacked substrate. A further, third substrate 22 is included, comprising vias for inserting FOP 14a, 14b. Multiple separate ECPs and metallizations 14a, 14b, 16a, 16b on the respective FOP 12a, 12b enable multi-substrate (or multi-chip) stacking with electro-optical interconnections. For example, ECP 14a connects electric contact points 46 and 48 at opposite sides of the substrate 22. A further electric contact point 88 on top surface of the substrate 22 and connectable to a pillar 96 through a conductive portion of a further via 86 is also illustrated. It is to be noted that also in this example Figure there are gaps, e.g. illustrated by reference 52, so the pedestals or pillars 90, 96 between the substrates are not (yet) connecting the substrates together.

In an embodiment, a single ECP 14 on a FOP 12 extends through two or even more substrates. For example, in a modified embodiment based on FIG. 5, a single metallization on FOP 12a (and/or 12b) covers FOPs 14a, 14b (and/or 16a, 16b) and the intermediate portion between these FOPs. This may enable to further simplify the structure in case of need to provide signal through multiple substrates 20, 22, e.g. to avoid at least some of the elements 30, 50, 48, 78, 96 between the substrates.

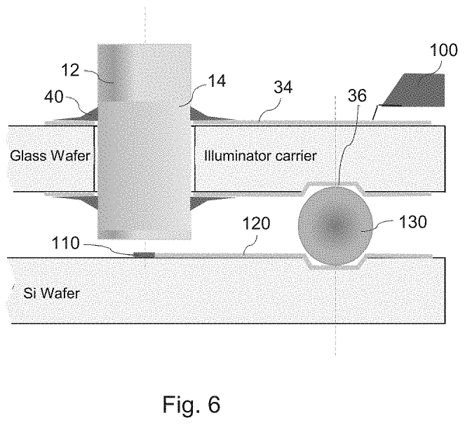

In an embodiment, the electric contact points or pads are configured for testing the photonic device by a test probe on the first substrate. Reference is made to the example structure of FIG. 6, for example for a quantum computing device, in which a via arrangement with the FOP 12 and the ECP 14 is inserted into a via of a glass wafer operative as a fiber holder and illuminator carrier. A test probe 100 is connected to an intermediate (lateral) electric connection line 34, forming an electric contact to the ECP 14. At the other side of the glass wafer, the ECP 14 is electrically connected to another electric connection line 36, which is connected to a sphere 130.

A meander 110, or in another embodiment a photodiode or a photonic device is adapted on top of a silicon wafer and positioned to receive optical signal from the FOP 12. A glass interposer may be applied between the wafers as intermediate layer. The meander is connected to the sphere 130 by an appropriate electric connection line 120. The sphere may be of metal, e.g. indium. The sphere enables to move the electrical contact layer 120 on the Si wafer (as the second substrate in the present example) to the electrical contact layer 36 on the glass wafer (as the first substrate in the present example). The sphere may thus deliver the signal between the lines (or layers) 120 and 36. The sphere may also facilitate alignment when overlapping the substrates, and optical axis alignment.

A benefit of this kind of structure is that connecting of the test probe at the meander chip level, e.g. at the other below side of the glass wafer, which is difficult to provide, can be avoided. The test probe 100 in the present example also illustrates that, as facilitated by the present arrangement of using fibers with ECP 14 into vias while interconnecting two sides of the same substrate and further substrate side by the sphere 130, it will be possible to perform electrical probing of not-easily reachable (or even impossible) contact pads to probe. After probing, the same pad can be used to perform electrical interconnections such as wire bonding, etc. It will be appreciated that an arrangement similar as illustrated in connection with FIG. 6 may be applied for many other applications, which do not include the test probe.

It is to be appreciated that there may be further layers, e.g. on top of the glass wafer, through which the via arrangement 10 may pass, potentially equipped with the ECP 14 extended through such further layer, or a separate ECP though the further layer.

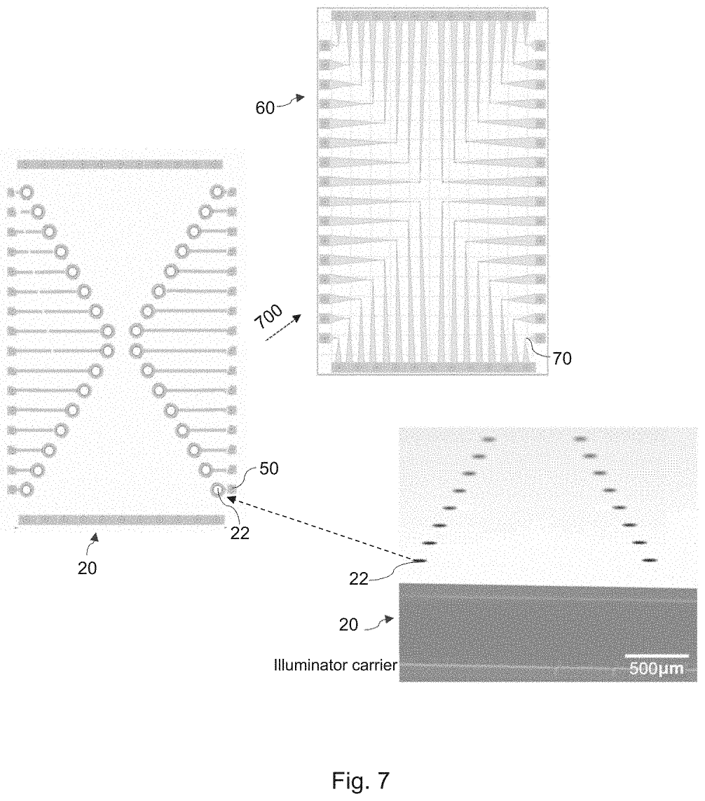

FIG. 7 illustrates a top view example of an apparatus, in which a (first) wafer 20 (also illustrated as 3D view on the right side below) operative as an illuminator carrier and comprising in this example 32 vias 22 for via arrangements 10 according to at least some of the above embodiments, such as the structure illustrated in FIG. 4, 5, or 6.

When presently disclosed via arrangements 10 are positioned in the vias 22, the respective ECPs 14 provide the electric connection between the electric contact point 50 and electric contact pad (32, not shown) on the other side of the substrate 20. The wafer is positioned 700 on top of the second wafer 60. The second wafer 60 comprises photonic devices or meanders 70 (or 110), which are adapted to receive respective optical signal from the FOP 12 through respective superimposed via 22. The photonic devices or meanders 70 may, via respective connection lines, be connected e.g. to further vias, electronic devices, electric interconnections or other elements, such as the sphere 130.

At least some of the above-illustrated features, and the via arrangement 10, may be applied for providing optical and electrical connectivity through single via 22 in wide variety of applications and devices, including quantum computing, silicon photonics, sensing, telecommunications, and MOEMS. For example, such MOEMS devices may include optical switch, optical cross-connect, vertical-cavity surface-emitting laser (VCSEL), or microbolometers, for which the present (electro-optical) via arrangement 10 may provide inter-substrate optical and electrical connectivity. Such devices are usually fabricated using micro-optics and standard micromachining technologies using materials like silicon, silicon dioxide, silicon nitride, gallium arsenide, and indium-fosfide. MOEMS devices may comprise components between 1 and 100 micrometers in size, and MOEMS devices generally range in size from few hundreds micrometers to a 20*20 square millimeter (or even larger) per device per wafer. Nanoscale devices with graphene structures from few nanometers to few hundreds of micrometers can be part of a device being illuminated using presently disclosed via arrangement.

A MOEMS device with the above-illustrated via arrangement may be fabricated, for example, by applying at least some features of the fabrication process illustrated below. Silicon over insulator (SOI) types of processes, as well as etching and doping processes may be applied. Even laser-machining technologies can be applied in precision drilling and etching processes.

In one example, the fabrication process may be based on micromechanical polycrystalline silicon deposition and sacrificial etching of supporting oxide layers. Sacrificial etching means that silicon oxide layers between and below polycrystalline membranes are partially removed during the process to release membranes and form free-standing structures. Main benefits of applying polycrystalline silicon include uniformity of deposition process, adaptable tensile stress, electrical conductivity and chemical selectivity against silicon dioxide during sacrificial etching. Diaphragm and the electrodes may be deposited of thin micromechanical polycrystalline silicon.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the preceding description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

1. An electro-optical device, comprising:
a planar first substrate,
a first electric contact point on a first side of the first substrate,
a second electric contact point on a second side of the first substrate,
a via arrangement configured to provide electric contact between the first electric contact point and the second electric contact point, wherein the via arrangement comprises a fiber optic portion and an electrically conductive portion, and the electrically conductive portion is arranged between the fiber optic portion and the first substrate and is configured to electrically connect the first electric contact point and the second electric contact point,
a second substrate, and
a photonic device on the second substrate,
wherein the fiber optic portion is adapted to extend towards the photonic device or connect the photonic device for illumination or light coupling to or from the photonic device, and wherein the electro-optical device comprises or is included in a quantum computing or cryogenic electro-optical module, and the photonic device is a fiber optic meander, a single-flux quantum electronic circuit or a photodiode of the quantum computing or cryogenic electro-optical module.

2. The device of claim 1, wherein the via arrangement is insertable into and removable from a through silicon or through glass via formed between the first side and the second side of the first substrate.

3. The device of claim 1, wherein at least one of the electric contact points is arranged for testing the photonic device by a test probe on the first substrate.

4. The device of claim 1, wherein the electrically conducting portion is a conductive coating around cladding of the fiber optic portion.

5. The device of claim 1, further comprising a third substrate, a third electric contact point on a first side of the third substrate, a fourth electric contact point on a second side of the third substrate, and a further via arrangement portion comprising a further electrically conductive portion provided around the fiber optic portion extending through the third substrate and configured to electrically connect the third electric contact point and the fourth electric contact point.

6. The device of claim 5, wherein a single electrically conductive portion around the fiber optic portion extends through the first substrate and the third substrate.

7. The device of claim 2, wherein at least one of the electric contact points is arranged for testing the photonic device by a test probe on the first substrate.

8. The device of claim 2, wherein the electrically conducting portion is a conductive coating around cladding of the fiber optic portion.

9. The device of claim 3, wherein the electrically conducting portion is a conductive coating around cladding of the fiber optic portion.

10. The device of claim 2, further comprising a third substrate, a third electric contact point on a first side of the third substrate, a fourth electric contact point on a second side of the third substrate, and a further via arrangement portion comprising a further electrically conductive portion provided around the fiber optic portion extending through the third substrate and configured to electrically connect the third electric contact point and the fourth electric contact point.

11. The device of claim 3, further comprising a third substrate, a third electric contact point on a first side of the third substrate, a fourth electric contact point on a second side of the third substrate, and a further via arrangement portion comprising a further electrically conductive portion provided around the fiber optic portion extending through the third substrate and configured to electrically connect the third electric contact point and the fourth electric contact point.

12. The device of claim 4, further comprising a third substrate, a third electric contact point on a first side of the third substrate, a fourth electric contact point on a second side of the third substrate, and a further via arrangement portion comprising a further electrically conductive portion provided around the fiber optic portion extending through the third substrate and configured to electrically connect the third electric contact point and the fourth electric contact point.

13. The device of claim 10, wherein a single electrically conductive portion around the fiber optic portion extends through the first substrate and the third substrate.

14. The device of claim 11, wherein a single electrically conductive portion around the fiber optic portion extends through the first substrate and the third substrate.

15. The device of claim 12, wherein a single electrically conductive portion around the fiber optic portion extends through the first substrate and the third substrate.
